(19) United States
(12) Patent Application Publication
(10) Pub. No.: US 2015/0268281 A1
(43) Pub. Date: Sep. 24, 2015

(54) System and method for monitoring, analyzing and acting upon electricity patterns

(71) Applicant: Neurio Technology Inc., Vancouver (CA)

(72) Inventor: Ali HAGHIGHAT-KASHANI, Vancouver (CA)

(21) Appl. No.: 14/555,640

(22) Filed: Nov. 27, 2014

Related U.S. Application Data
(60) Provisional application No. 61/955,414, filed on Mar. 19, 2014.

(51) Int. Cl. G01R 21/00; G06Q 30/02; G06Q 50/06

(52) U.S. Cl. CPC G01R 21/00; G06Q 50/06; G06Q 30/0267

(57) ABSTRACT

Electricity patterns at a location are monitored and analyzed. The electricity data is processed to determine a state of the devices at the location or a state of the location itself, and information relating to such is provided to a user interface, a cloud service or a smart device within the group of devices at the location. Upon receipt of such information, the user may act, a smart device may change its state, or a cloud service system may take an action. Cloud service systems may form part of an insurance company, a security company, an advertisement serving company or a health monitoring company. The state of the devices within the location can be determined without necessarily placing sensors at every device. A game type application may be used to induce homeowners to reduce their electricity consumption.

### TECHNICAL FIELD

This application relates to systems and methods for monitoring, analyzing and acting upon electricity patterns. More particularly, this application relates to analyzing electricity patterns attributed to one or more individual devices within a group of devices that are collectively monitored, and taking action depending on such analysis.

### BACKGROUND OF THE INVENTION

Buildings such as homes and offices are increasingly utilizing technology to improve energy efficiency, including the use of smart meters offered by utilities, energy saving programs, and so on. Energy management is a term that generally relates to or is implemented by systems, processes and devices in order to reduce energy consumption and understand energy consumption patterns. This can occur in private homes, in businesses, in manufacturing facilities and in public sector or government organizations, to name a few.

From the perspective of an energy consumer, the process of monitoring, controlling, and conserving energy in a building or organization typically involves: metering (in some fashion) energy consumption and collecting the data; understanding the raw data and/or collecting data that is useful; finding opportunities to save energy, and estimating how much energy each opportunity could save; taking action to target the opportunities to save energy (i.e. addressing the routine waste and replacing or upgrading inefficient equipment); and tracking progress by analyzing meter data to see how well the energy-saving efforts have worked. For example, an individual could analyze her meter data to find and quantify routine energy waste, and might also investigate the energy savings that could be made by replacing equipment (e.g. lighting) or by upgrading a building's insulation.

One approach to energy-data collection is to install interval-metering systems that automatically measure and record energy consumption at short, regular intervals such as every hour, every 15-minutes, or even every few seconds when needed. This detailed interval energy consumption data makes it possible to see patterns of energy waste that it would be impossible to see otherwise: for example one can ascertain how much energy is being used at different times of the day or on different days of the week. Using the detailed interval data, it is possible to make broad brush estimates of how much energy is being wasted at different times. For example, if a person identifies that energy is being wasted by electronics left on over the weekends, one can (a) use interval data to calculate how much energy in kWh is being used each weekend, (b) estimate the proportion of that energy that is being wasted, for example by electronics that should be switched off and (c) using the figures from (a) and (b), calculate an estimate of the total kWh (kilowatt hours) that are wasted each weekend. This type of data and information is in bulk, aggregate form and is not particular or granular.

Using power sensors on every device, it is possible to acquire an itemized bill that shows usage and energy cost for various appliances. With itemized data, consumers can take action to conserve, by either installing more energy efficient appliances (e.g. air conditioners, clothes washers/dryers, hot tubs, ovens, lighting, etc.), or changing their usage patterns in areas where pricing of electricity varies by time of day, or simply turning loads off when not in use. The problem is that people do not want to incur the significant expense required to install power sensors on each of their appliances and electric loads. This underscores the significant problems: (a) while there is some value to the bulk aggregate data, it is not the definitive picture in energy management, in fact, it barely scratches the surface of what should be possible and available to power consumers; and (b) load disaggregation or cataloguing power usage at a granular level is difficult to currently achieve. Even if power sensors are attached onto every single appliance in a home, there is still the issue of the value of the produced raw data without further enhancements.

From the perspective of the consumer, as opposed to utility companies, there are some overlapping but also different concerns in regards to power usage. With the advent of smart grid technologies, also called smart home, smart meter, or home area network (HAN) technologies, optimized demand reductions became possible at the end-use or appliance level. Some smart grid technologies have provided the ability to capture real-time or near-real-time end-use data and have enabled two-way communication. Smart grid technologies currently exist for at least some percentage of a utility's customer base and applications are growing. From a consumer perspective, smart metering offers a number of potential benefits to householders. These include the provision of a tool to help consumers better manage their energy use. Smart meters with a display can provide up-to-date information on gas and electricity consumption in the currency of their country and in doing so help people to better manage their energy use and reduce their energy bills and carbon emissions.

Various load disaggregation algorithms have been suggested in the literature. One technique of disaggregating the power signal measured at the incoming power meter into its constituent individual loads is known as Single Point End-use Energy Disaggregation (SPEED™), and is available from Enetics, Inc. of New York. The SPEED™ product includes logging a premises' load data and then transferring the data via telephone, walk-ups, or alternative communications to a master station that processes the recorded data into individual load data, and acts as a server and database manager for pre- and post-processed energy consumption data, temperature data, queries from analysis stations, and queries from other information systems.

### SUMMARY

There is provided herein a system for monitoring and analyzing electricity at a location having multiple devices, the system comprising: one or more electricity data sensors; one or more processing modules connected directly or indirectly to said sensors, configured to receive output from the sensors; a communication module connected to and receiving output from the processing modules; and a user interface connected to the communication module. The processing modules are configured to monitor electricity patterns of the location and determine, from the patterns, states of the devices within the location, without there being an electricity data sensor individually dedicated to every device for which a state is determined; and the communication module is configured to send a notification of a determined state to one or more of the user interface, a smart one of said devices, and a cloud service.

Also provided herein is a method for monitoring and analyzing electricity at a location having multiple devices, the method comprising: sensing electricity data in one or more places at the location; monitoring electricity patterns of the location; determining, from the electricity patterns, states of the devices within the location, without there being an electricity data sensor individually dedicated to every device for which a state is determined; and communicating a notification of a determined state to one or more of a user interface, a smart one of said devices, and a cloud service.

Further provided herein are one or more computer readable storage media comprising computer executable instructions, which, when executed, cause one or more processors to: receive sensed electricity data from one or more places at a location; detect an electricity data signature; determine a device that is associated with the signature by one or more of: comparing the detected signature with a local library of stored signatures; comparing the detected signature with an external library of stored signatures; and comparing the detected signature with a device behavior model. The processors also monitor electricity patterns of the location; determine, from the electricity patterns, states of the devices within the location, without there being an electricity data sensor individually dedicated to every device for which a state is determined; communicate a first notification of a first determined state to a user interface, wherein the first determined state is an “on” state of a selected one of said devices that is different from an immediately preceding “on” state of said selected device, and the selected device does not have a dedicated electricity data sensor; communicate a second notification of a second determined state of a non-smart one of said devices to a smart one of said devices, upon which the smart device changes its own state; and communicate a third notification to a cloud service, receive from the cloud service an advertisement related to the determined state, and display the advertisement on the user interface.

Furthermore, the system disclosed may be further configured to: retrieve at least one further electricity consumption for at least one further location; compare said electricity consumption to said at least one further electricity consumption; calculate a score or ranking based on how low said electricity consumption is compared to said at least one further electricity consumption; and display said score or ranking on the user interface.

### BRIEF DESCRIPTION OF THE DRAWINGS

Embodiments will now be described by way of example only with reference to the appended drawings, which should not be taken to be limiting.

FIG. 1 is a block diagram illustrating an example of a configuration for a system operable to monitor electricity patterns.

FIG. 2 is an exemplary, schematic representation of sensors and devices that may be connected together at a common location as part of a system to monitor electricity patterns.

FIG. 3 is a flow diagram illustrating example computer executable operations for monitoring electricity patterns in a location.

FIG. 4 is a flow diagram showing exemplary steps in a method for detecting a change in state of a device that is switched on.

FIG. 5 is a flow diagram showing exemplary steps in a method for determining the device that an electricity data signature corresponds to.

FIG. 6 is a flow diagram showing exemplary steps in a method for detecting an event in a first device and causing a second device to act.

FIG. 7 is a flow diagram showing exemplary steps in a method for detecting and acting upon a malfunction on a device.

FIG. 8 is a flow diagram showing exemplary steps in a method for detecting a pattern of usage of a device and acting proactively upon it.

FIG. 9 is a flow diagram showing exemplary steps in a method for detecting a risk in a device and providing notifications about it.

FIG. 10 is a flow diagram showing exemplary steps in a method for detecting a change in pattern of electricity usage and informing a health monitoring system.

FIG. 11 is a flow diagram showing exemplary steps in a method for detecting an old device and providing ads for a replacement.

FIG. 12 is a flow diagram showing a gamified process for monitoring a user's electricity consumption.

### DETAILED DESCRIPTION

For simplicity and clarity of illustration, where considered appropriate, reference numerals may be repeated among the figures to indicate corresponding or analogous elements. In addition, numerous specific details are set forth in order to provide a thorough understanding of the examples described herein. However, it will be understood by those of ordinary skill in the art that the examples described herein may be practiced without these specific details. In other instances, well-known methods, procedures and components have not been described in detail so as not to obscure the examples described herein. Also, the description is not to be considered as limiting the scope of the examples described herein.

It will be appreciated that the examples and corresponding diagrams used herein are for illustrative purposes only. Different configurations and terminology can be used without departing from the principles expressed herein. For instance, components and modules can be added, deleted, modified, or arranged with differing connections without departing from these principles.

The electrical wiring in buildings has been likened to a nervous system that connects all electronics, including electrical devices, to a central place such as the breaker panel or the meter box. The system described herein introduces artificial intelligence to all existing electronic devices by monitoring the electricity patterns of the building's electrical network.

The electrical patterns can be used to identify which appliances are being operated at any time, determine what activities occupants are performing, and compute or otherwise determine the status of the premises (e.g., occupants present, away, asleep, etc.), to name a few examples.

Such a system may here also be referred to as a “Power Graph”, generally representing a global mapping of all devices that are connected or otherwise plugged in. Having a dataset that depicts usage events, patterns and relations of electronic devices enables various applications including improvements to occupant experience (e.g., providing alerts upon detection of mistakes and hazards, reminding users to perform actions, reminding users to conserve energy, etc.). The Power Graph can also help service providers in industries such as security, insurance, remote healthcare, electric utility, solar, retail, electric manufacturers, market intelligence, etc.

The system described herein may be configured, in at least one example, to gather electricity data relating to a building or premises, including energy used, real power usage, reactive power usage, power factor, current, and voltage. This information can be obtained from one or multiple sensors installed across the electrical network. One way to implement this is to place a sensor inside the breaker panel to monitor the main electrical lines entering the premises. Another way would be to utilize smart metering infrastructure that exists in many households. There could also be sensors placed at one or more individual plugs. The system may report total aggregate information, as well as individual phase data, or individual plug data, depending on the setup.

There is also provided a system that processes the collected data inside the premises. This can be to perform pre-processing steps and prepare the data for communication, or it can process the data further to identify events, trigger actions, or raise alerts.

The system may also be configured to communicate raw data and/or processed results to other systems, including users, cloud services used for further processing, or other electronic devices that may change their state as a result.

A processing system outside of the premises is also described herein, such as a cloud service, that analyzes the data to identify the state of the premises, its occupants, and its electronic devices. Some or all of the electricity data may be sent to the external system for at least some of the processing. This outside or external system can present the results to occupants, to other connected services such as external web or mobile applications, or to electronic devices that may change their state as a result.

User-facing applications on mobile, web, wearable and other similar platforms are also provided, to display to the users the resulting information, obtained from the sensor and the processing systems. The system can also capture user input to refine analyses and provide a more refined experience. For instance, users may be asked to provide a list of appliances in their house, confirm when a given appliance has been used, enter demographic information, etc. The user-facing application is also used to inform users of important events, such as providing real-time notifications when an appliance is left on, or when over consumption of energy occurs, or when a device malfunctions. The user-facing interface can be configured as a text messaging service that does not require a custom user application. The user interface may also include a feed of activities, tips, other users' activities, and other content relevant to user experience at that location such as bills and news updates from other service providers (e.g., telecom, electricity, security, etc.). In addition to such activities, this feed can include a social feed to help engage the community of users and provide them with feedback from their peers.

Systems and services such as smart appliances, connected electronics, as well as third party web solutions, that can pull data about location and device states, or receive notifications when events of interest occur may also be provided. For example, a WiFi-connected power bar can turn itself off when it receives a notification that users have left the location or gone to sleep.

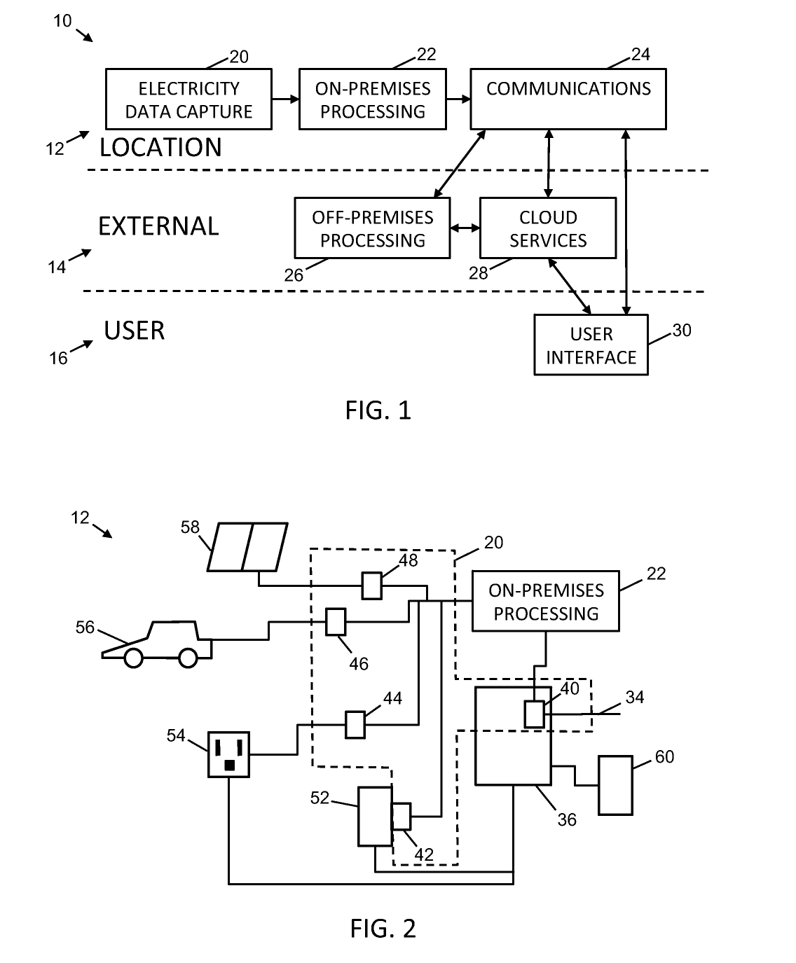

Turning now to the drawings, FIG. 1 illustrates an example of a system 10 for monitoring, processing, and utilizing data associated with electricity patterns. In this example configuration, there are three environments, a location (e.g. a house, a business, a premises, etc.) 12, an external environment 14, and a user environment 16. The location 12 includes an electricity data capture module 20, an on-premises processing module 22 for processing captured electricity data, and a communications module 24 for communicating with the external and user environments 14, 16. The electricity data capturing module 20 may include one or more sensors or other electricity capturing devices. The external environment 14 includes an out-of-premises processing module 26 for performing external processing operations, and a cloud services (or connected services) processing module 28 for interfacing with other services. The cloud services may be part of the system 10, or they may be part of a third party system. The user environment 16 includes one or more user interfaces 30 to enable a user to interact with the system 10. The system 10 is configured to monitor electricity patterns of the location 12 and determine at least one of a state of the location and a state of at least one of the devices within the location, without placing sensors at every device for which a state is determined.

FIG. 2 shows more detail of a portion of the location 12 of an exemplary system 10. A main supply 34 feeds electricity into the location 12 at a breaker panel 36. The electricity data capturing module 20 includes at least one main sensor 40. This main sensor 40 is connected to or around the main supply line to the location 12 and detects the total amount of current flowing into the breaker panel 36. Further, optional sensors 42, 44, 46, 48 are connected respectively and dedicated to devices such as an appliance 52, a socket 54, an electric vehicle 56 and a solar panel 58 at the location. These optional, dedicated sensors 42, 44, 46, 48 may be attached to or around a power supply line to the devices 52, 54, 56, 58 or may be incorporated in the devices themselves. The optional sensors may measure the electricity usage or generation by each of the devices to which they are connected. Note that there is at least one device 60 that is powered via the panel 36, but for which there is not a dedicated sensor. Such device 60 is a non-smart device, in that it is unable to proactively inform the system 10 or other devices at the location of its state. Other devices connected to the location may be smart devices, and as such may be configured to receive notifications and act upon them. Such smart devices may or may not have dedicated sensors for capturing electricity usage. All the sensors 42, 44, 46, 48 are connected, wirelessly or via wires, to the on-premises processing module 22. Note also that the on-premises processing may alternately be located inside the breaker panel 36.

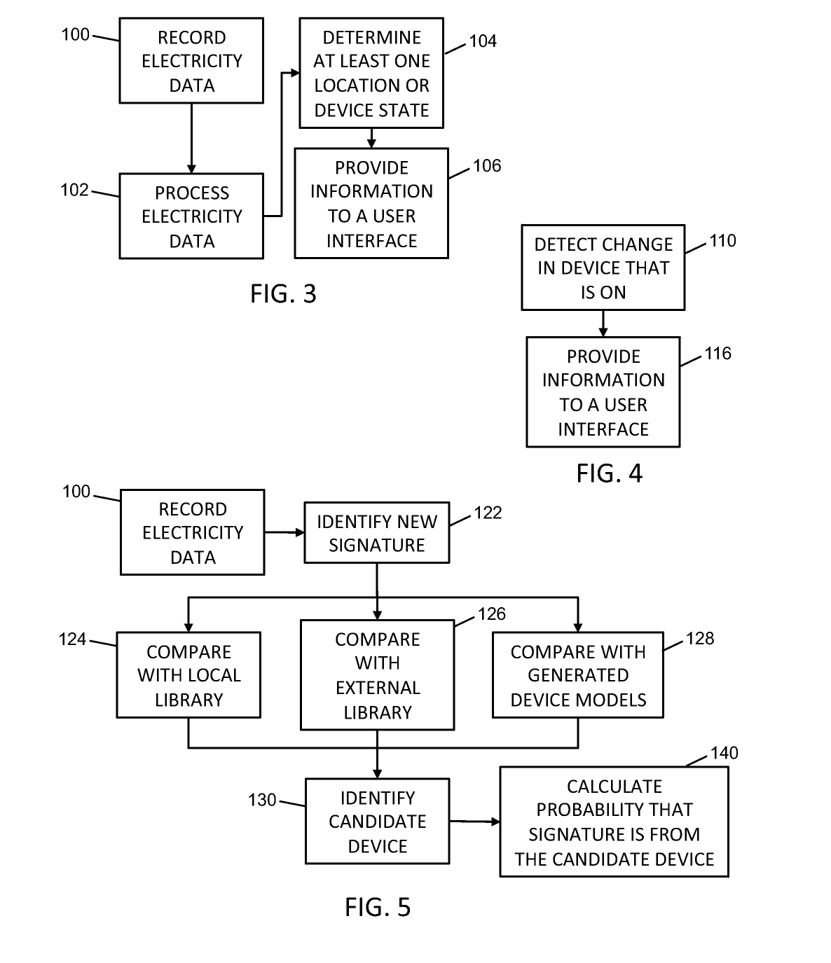

FIG. 3 illustrates an example of a process performed by system 10, comprising recording electricity data at 100, processing the data at 102, determining at least one location or device state at 104, and providing suitable information to a user interface at 106. The device state that is determined in step 104 may be whether it is on or off, whether it is in a particular power mode, or what its power consumption is. If it is the location state that is determined, it may be the real-time electricity consumption of the location.

An example use of the system 10 is described as follows. A main electricity sensor 40 can be installed inside the breaker panel 34 to monitoring the main power line. Data can be captured periodically (e.g. every second), preprocessed it to remove noise, and pushed to a cloud service through a WiFi connection on the communications module 24 and an Internet router. The cloud service receives the data and analyzes it to detect important events, such as when an oven has been turned on. Upon detection of the event, the cloud services notifies the user's mobile application that an oven has been detected, and the user is prompted to set an alarm for when they expect their meal to be ready. A few minutes later, when the oven is done preheating as it reaches the target temperature, the cloud generates another notification to a mobile application (i.e. a mobile user interface 30) informing the user that the oven is preheated and ready to be used. FIG. 4 shows the steps the system 10 may take in such a case, i.e. after determining the state of the oven. In step 110, the system 10 detects that the state of a device, which is already switched on, changes. In step 116, the system 10 provides information relating to the changed state of the device to the user interface 30. Finally, if the oven continues to stay on hours after initial use, the cloud service 28 will issue a text message alert to the user informing them that the oven is still on.

As illustrated in FIG. 1, the processing of the electricity data can be performed both on-premises and off-premises, outside of or remote from the location. The electricity data is recorded at a rate that may range from one sample per hour, up to thousands of samples per second, for example. The captured data may be bundled at regular intervals and transmitted to the on-premises processor 22. The recording and transmission rate are determined by the necessities of the application.

The processing of the data is performed to compress data volume, filter noise, identify device events (e.g., turning on/off or changing state), identify user actions (e.g., doing laundry), determine location and device state, learn and predict events, behaviors and actions, etc.

Identifying electronic devices based on the aggregate electricity data of more than one device (e.g., the aggregate electricity data) is often necessary to determining the state of the location and the actions of the user. In order to do this, the processing system searches for device signatures within the aggregate data. The signatures often contain information such as the changes in power draw when the device is turned on or off, the transient signatures at such trigger moments in real power as well as reactive power, the overall shape of the device cycles over a given period of time, the frequency of such cycles, the duration of the device signature, the noise level in the power data while the device is in operation, etc.

As shown in FIG. 5, the processing system 22 and/or 26 of FIG. 1 may, after the electricity data is recorded in step 100, compare the recorded characteristics to stored instances from an existing library of devices, such as those of other users, as well as the device events previously identified by the users of the same location. A new signature in the electricity data is identified in step 122. The new signature is then compared, in step 124, with a local library of stored signatures. If the new signature is found to be similar to a stored signature of an existing, candidate device in the location, then, in step 130, this finding can be used to estimate the probability, in step 140, of the new signature being the result of the operation of the candidate device. The comparison, in step 126, of signatures of devices belonging to other users complements this process by providing means to identify signatures that may not be accurately matched to signatures that are associated with the same location. Finally, in step 128, it is also possible to use generated device behavior models instead of comparing against previously stored instances. For instance, knowing that an average fridge cycles forty times a day, a model can be generated that identifies devices with a similar daily cycle count as a fridge. One, two or all of the comparison steps 124, 126, 128 may be used in the calculation that links a newly identified electricity data signature with a device.

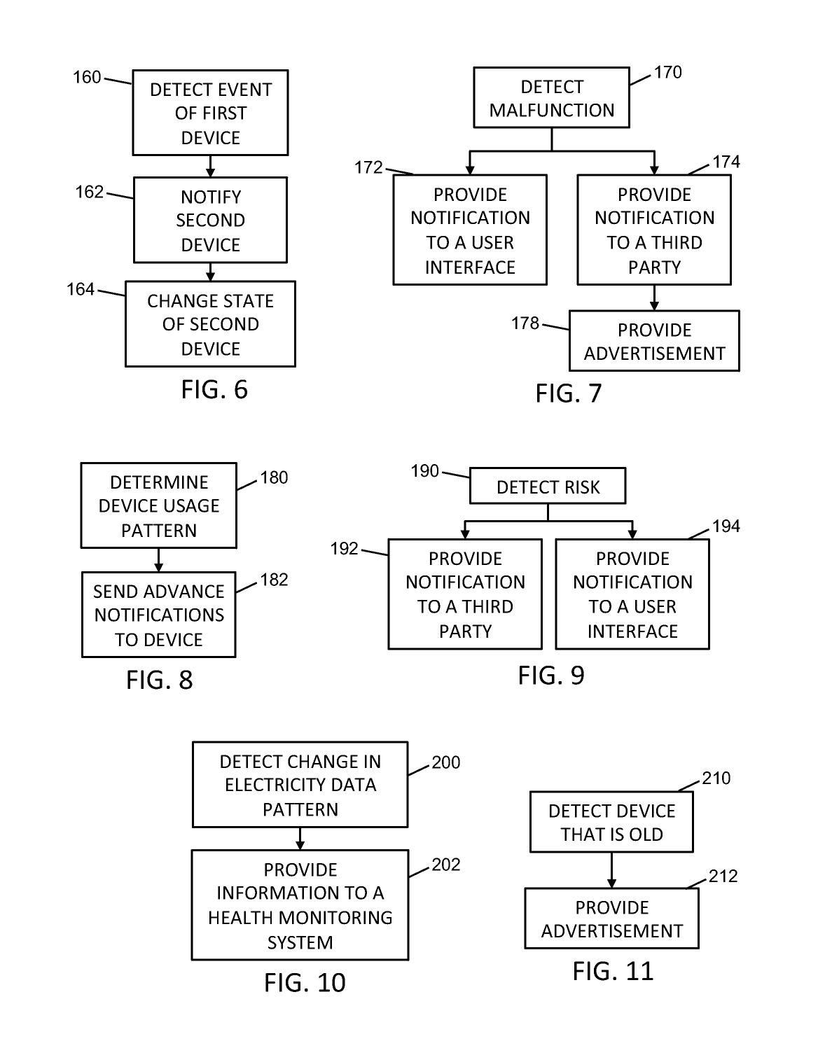

The tools used to match new signatures against existing models and libraries include statistical analysis as well as machine learning. The learning capabilities in the system enables the addition of artificial intelligence to existing non-smart devices, as well as to new smart ones. A self-learning home, for instance, can adjust itself to user needs, like adjusting lighting and temperature as soon as the garage door is opened and its signature detected by this system. This is shown in FIG. 6. In step 160, an event of a first device, such as opening of a garage door, is detected. In step 162, a second electrical device that is connected to the location is notified, such as a smart lighting device. In step 164, the notification to the second device results in the second device changing its state, which in this case would be from off to on.

The system 10 can operate in real-time, after the fact, or both, to create an intelligence that is shared with the user and his other devices at the location and/or services to which he subscribes.

### Applications

The technology described herein may be used to observe existing (non-smart as well as smart) devices within location, and additionally, by sharing the knowledge obtained from this process, to introduce artificial intelligence to devices. The intelligence leads to timely notifications and alerts to users, and seamless adjustments to the device states (for devices with connectivity) based on user behavior, previous or current actions, and predicted desires.

To an end-user, the monitoring and intelligence capability described here brings together a user's device experience into a single platform, which he can access through a variety of interfaces described earlier in order to observe the devices and manage the experience. Therefore, this technology provides a homepage for locations such as homes or offices. The single platform may be a central application for the occupants of a given location, allowing them to observe and manage their experience with the host of electronic devices present. Such a central application unifies the management of both smart and non-smart devices.

The system 10 effectively repurposes the electrical network of a premises into an intelligent network of devices that can learn from user behavior and adapt to it. The system 10 can be used to introduce artificial intelligence to smart or connected devices in an Internet-of-Things.

Below is a list of some example applications for utilizing a system 10 such as that shown in FIG. 1:

### Energy Management:

Using the technology described above, users can be provided with energy management features that display household energy use, break it down by individual devices and behaviors, compare it against other users, and provide tips and relevant content on managing energy. For instance, when an AC (air conditioner) is left on, the user can be notified to take action to preserve energy and costs.

In addition to consumption, users with alternative energy sources can also use the sensing and analytics component to measure each source and gain an understanding of how energy is generated and consumed. Users with solar panels can monitor their solar generation and the system 10 can alert them when their solar panels are producing less than normal energy. For example, now referring to FIG. 7, the system 10 may detect a malfunction in a connected device in step 170. In step 172, the system 10 provides a notification to a user interface that there is a malfunction in the device. Further, the system 10 may also provide a notification to a cloud service, such as an advertiser, in step 174. The cloud service would then, in step 178, provide via the system 10 and user interface 30, one or more ads related to the repair or maintenance of solar panels.

Finally, the sensing and analytics presented here can be used to manage multiple energy sources such as homes that have solar panels, storage batteries, EV (electric vehicle) batteries, as well as the grid. The system 10 can be used to decide, based on consumption patterns, available energy and generation potential, when the best times are to charge batteries or draw from them. The system 10 can also be used to decide when solar generation should be output to the grid and when to use the grid for consumption and battery charging. The system 10 can be used for providing solar consumers with intelligence on how their electricity consumption compares to their electricity generation, and intelligence on how to optimize their electricity network to pull energy from the most cost-efficient source at a given time.

Also the monitoring and management of these sources can also benefit energy trading markets by controlling the grid at a micro level to optimize supply and demand.

Energy management applications described above can benefit industries such as electric utilities, solar generation, battery management, and energy trading.

### Smart Home:

The monitoring and artificial intelligence capabilities in this presented system can transform the collection of electronics in a given location to become aware of each others' state and of the occupants' actions, habits, and desires. For instance, a smart coffee maker can receive a notification every morning right before the users are expected to wake up, if the users are observed to brew coffee every morning. This is shown in FIG. 8, where in step 180 the system 10 determines a pattern of usage of a particular device. Following this, in step 182, the system 10 sends an advance notification to the particular device, informing it to switch on.

The home intelligence application described here can benefit the smart home industry through integration with other vendors, and the system can also benefit other industries such as cable/telecom, and retail, which are looking for new products and services to provide to their customers as an entirely new line or a value add on existing product lines.

### Safety:

Another use of this application is for safety monitoring and notification. If risky behaviors or mistakes are detected, occupants or safety service providers can be alerted in real-time. For example, if an iron is left on by accident, the system will notify the occupants or those in charge of their safety. This also extends to notifying users when a device malfunctions and can risk damages to itself or its environment. For example, if a water heater is observed to malfunction, the system can notify users in advance of a possible flooding. This can be seen by referring back to FIG. 7, in which the malfunction is detected in step 170 and then the notification is provided to the user interface 30 in step 172.

Now referring to FIG. 9, this application can be used by industries such as home security providers who wish to provide additional protection to their customers, or by insurance companies who wish to minimize risks of fire and damage, and be notified along with the user when such risks are imminent. Such risky behaviours can be deterred by alerting users as well as the possibility of adjusting insurance premiums to encourage responsible behaviors. In step 190, following the determination of a state of a device (such as in step 104 of FIG. 3), the system 10 identifies a risk. In step 192, the system 10 provides a notification to a third party, such as a security provider or an insurance company. In step 194, the system 10 also provides a notification to the user interface 30.

### Healthcare:

This technology can be used for or as part of a non-invasive health monitoring and notification system, as shown in FIG. 10. Users' lifestyles can be monitored and quantified to provide valuable feedback on matters such as cooking habits, bathroom visits, etc. Furthermore, for giving care to the elderly or the disabled, additional observations can be made of their ongoing state of well-being (e.g., leaving bed in the morning when “awake” electrical behavior is observed, or cooking meals frequently, etc.). This application can benefit the healthcare industry by quantifying user lifestyle and providing early warnings when patterns deemed high-risk are observed, so that healthcare workers can take timely action. For example, in step 200, the system detects a change in the pattern of electricity data from a normal to a high-risk pattern, and then, in step 202, provides information indicative of an early warning to a health monitoring system.

### User Analysis:

The observed data and the analyzed results, paired with user-inputted information such as their demographics, can be used to classify users, determine their use behaviors of various devices, and predict their needs and interests.

Such analyses can be used for a number of services. First, they can be used to offer users targeted advertising. Leads can be created for services and products, and presented to users through the variety of user interfaces listed above (e.g., mobile, web, wearable, etc.). The products and services may relate to what is used by users within the location, or be relevant to them as predicted by their general demographic and predicted interest. For example, a user with an old fridge may be provided with promotions for a new energy saving fridge. This is shown in FIG. 11, where in step 210, the system detects that a particular device is old, either by determining that it consumes significantly more energy than currently available fridges, by detecting one or more malfunctions, by determining that its energy consumption has steadily increased over time, or by having recorded how long the fridge has been in service. In step 212, the system 10 provides targeted ads to the user interface that relate to offerings of a new, replacement device. As another example, a user with many connected devices may be presented with ads for a new internet service; and all users can be presented with contact information of service providers and tradesmen such as electricians, carpenters, plumbers, etc. based on a variety of observations and information obtained about the users and the location.

Another use for the user analysis is for electronic manufacturers that wish to understand how their products are used, and how the user experience can be improved. For instance, if one brand of dishwashers are mostly used with a specific configuration, the user interface may be improved to make that use case more accessible, or clarify why and when other configurations can be beneficial to users.

### Gamification:

It is possible to add a gamified (i.e. adapted to have elements of a game) process to the user application to help people understand where their energy use is going. To help users understand how energy is consumed in their home, they can be presented with a real-time measurement of their home's power draw, and be provided with instructions and tips as to how to identify sources of energy use in the home. This can be accomplished through desktop, web or mobile applications that help users walk through their home to observe the energy usage of various devices by asking the users to change their state or plug them in or out.

To further encourage users to educate themselves using this tool as well as to make the information more meaningful to them, this process can be gamified by introducing comparable measurements from other users. For example, a user can be presented with their ranking in their community in terms of how efficient their baseload is (i.e. baseload is the amount of energy consumed when home is at rest and only always-on devices remain powered). Besides the baseload value, a scoring and leaderboard approach can be applied to other measurements such as the home's minimum power usage in a given period of time, the home's average energy usage in a given amount of time, etc.

One specific implementation of a gamified educational tool, for understanding how energy is used at home, is an application that displays the real-time power and the minimum power ever achieved. The users are then instructed to walk around the home and turn off all lights and appliances, then unplug remaining devices, and continue until the power draw reaches the smallest possible number. Their minimum power score is compared against that of other users in real-time to put their home's energy efficiency in the context of other homes. Through this process, users are empowered to identify devices that use more power than they expected, or draw power while they're off.

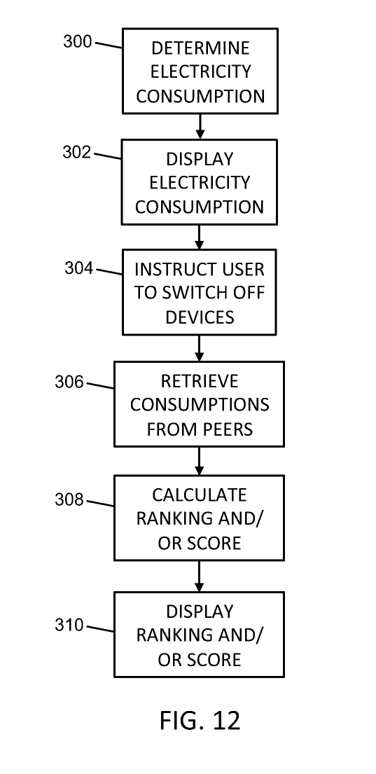

Referring to FIG. 12, a process is shown of a gamified electricity consumption monitor running as an app on a user device. In step 300, the system 10 determines the power or electricity consumption of a location, such as a user's home. The consumption may be the real-time consumption, an average consumption, a minimum consumption or a baseload consumption. In step 302, the system displays the electricity consumption via a user interface 30, such as a user interface of a user's smart phone. In step 304, which may be optional, the app outputs an audible and/or visible message that instructs the user to switch off or power down devices in the user's home. In step 306, the system, since it can be connected to multiple separate locations, retrieves electricity consumption levels from peers of the user, a peer being either literal or a user with a similar home, or a neighbor, or someone in the same city, for example. In step 308, the system 10 calculates a ranking and/or score of the user's electricity consumption compared to the consumption of the peers. Better scores or rankings will be calculated for lower electricity consumptions. In step 310, the results of the ranking and/or scoring are displayed on the user's smart phone. Rankings and/or scores may be based on real-time electricity consumption, average consumption, minimum consumption and/or baseload. There are also other ways in which scoring or ranking may be implemented. Calculating a score may be synonymous with calculating a ranking. The score and/or ranking may be updated as the user walks around the location unplugging various devices or powering them down, and as such the process may loop back to step 302 repeatedly.

It will be appreciated that any module or component exemplified herein that executes instructions may include or otherwise have access to computer readable media such as storage media, computer storage media, or data storage devices (removable and/or non-removable) such as, for example, magnetic disks, optical disks, or tape. Computer storage media may include volatile and non-volatile, removable and non-removable media implemented in any method or technology for storage of information, such as computer readable instructions, data structures, program modules, or other data. Examples of computer storage media include RAM, ROM, EEPROM, flash memory or other memory technology, CD-ROM, digital versatile disks (DVD) or other optical storage, magnetic cassettes, magnetic tape, magnetic disk storage or other magnetic storage devices, or any other medium which can be used to store the desired information and which can be accessed by an application, module, or both. Any such computer storage media may be part of the system 10, any component of or related to the system 10, etc., or accessible by or connectable thereto. Any application or module herein described may be implemented using computer readable/executable instructions that may be stored or otherwise held by such computer readable media.

The steps or operations in the flow charts and diagrams described herein are just for example. There may be many variations to these steps or operations without departing from the principles discussed above. For instance, the steps may be performed in a differing order, or steps may be added, deleted, or modified. Also, two or more of the various flowcharts may be combined in multiple ways.

Although the above principles have been described with reference to certain specific examples, various modifications thereof will be apparent to those skilled in the art as outlined in the appended claims.

1. A system for monitoring and analyzing electricity usage at a location, the system comprising:
multiple devices at the location that use electricity;
one or more electricity data sensors;
one or more processing modules connected directly or indirectly to said sensors, configured to receive output from the sensors;
a communication module connected to and receiving output from the processing modules; and
a user interface connected to the communication module;
wherein:
the processing modules are configured to monitor electricity patterns of the location and determine, from the patterns, states of the devices within the location, without there being an electricity data sensor individually dedicated to every device for which a state is determined; and
the communication module is configured to send a notification of a determined state to one or more of the user interface, a smart one of said devices, and a cloud service.

2. The system of claim 1 wherein the communication module is configured to send the notification to the user interface.

3. The system of claim 2, wherein the determined state is an “on” state of a selected one of said devices that is different from an immediately preceding “on” state of said selected device.

4. The system of claim 3, wherein none of said one or more electricity data sensors is dedicated to the selected device.

5. The system of claim 2, wherein:
the determined state notified to the user interface is that a device, without a dedicated sensor, is old; and
the system sends to the user interface an advertisement for a new device to replace the old device.

6. The system of claim 2, wherein the determined state notified to the user interface is an abnormality.

7. The system of claim 6, wherein the abnormality is a safety hazard or a malfunction.

8. The system of claim 1 wherein:
the determined state is a state of a non-smart one of said devices; and
the notification is sent to said smart device, upon which the smart device changes its own state.

9. The system of claim 1, wherein the determined state notified to the user interface is notified to a cloud service.

10. The system of claim 9 wherein the cloud service provides a notification related to the determined state to the user interface.

11. The system of claim 9, wherein the cloud service is a health monitoring system, an insurance system or a security system.

12. (canceled)

12. The system of claim 1 wherein the processing modules detect an electricity data signature and determine a device that is associated with the signature by one or more of:
comparing the detected signature with a local library of stored signatures;
comparing the detected signature with an external library of stored signatures;
and comparing the detected signature with a device behavior model.

13. The system of claim 1, wherein a state of the location is determined.

14. The system of claim 13, wherein:
the determined state of the location is notified to a cloud service; and
an advertisement related to the determined state of the location is provided by the cloud service and displayed on the user interface.

15. The system of claim 1, wherein:
at least one of the processing modules is remote from the location;
at least some of the processing is performed remote from the location; and
at least some of the processing is performed at the location.

16. The system of claim 1, wherein the system operates in at least one of real-time or after the fact.

17. The system of claim 1 that repurposes the electrical supply network into an intelligent network of devices that learns from and adapts to user behavior.

18. The system of claim 1, wherein the user interface is part of an application for occupants of the location to observe and manage said devices.

19. The system of claim 1, configured to send a notification to the user interface that compares electricity consumption at the location to electricity generation at the location, and indicates how to optimize drawing energy from different electricity sources at a given time.

20. The system of claim 1, configured to determine when to charge batteries at the location and when to use them as an source, based on user consumption behavior and availability of energy from available sources.

21. The system of claim 2, wherein the state is an electricity consumption of the location, the system further configured to:
retrieve at least one further electricity consumption for at least one further location;
compare said electricity consumption to said at least one further electricity consumption;
calculate a score or ranking based on how low said electricity consumption is compared to said at least one further electricity consumption; and
display said score or ranking on the user interface.

22. A method for monitoring and analyzing electricity at a location having multiple devices, the method comprising:
sensing electricity data in one or more places at the location;
monitoring electricity patterns of the location;
determining, from the electricity patterns, states of the devices within the location, without there being an electricity data sensor individually dedicated to every device for which a state is determined; and
communicating a notification of a determined state to one or more of a user interface, a smart one of said devices, and a cloud service.

23. The method of claim 22 wherein:
the notification is communicated to the user interface;
the determined state is an “on” state of a selected one of said devices that is different from an immediately preceding “on” state of said selected device; and
the selected device does not have a dedicated electricity data sensor.

24. The method of claim 22 wherein:
the determined state is a state of a non-smart one of said devices; and
the notification is sent to said smart device, upon which the smart device changes its own state.

25. The method of claim 22, wherein the determined state is notified to the cloud service the method further comprising:
receiving from the cloud service an advertisement related to the determined state; and displaying the advertisement on the user interface.

26. The method of claim 22, further comprising:
detecting an electricity data signature; and
determining a device that is associated with the signature by one or more of:
comparing the detected signature with a local library of stored signatures;
comparing the detected signature with an external library of stored signatures; and
comparing the detected signature with a device behavior model.

27. One or more computer readable storage media comprising computer executable instructions, which, when executed, cause one or more processors to:
receive sensed electricity data from one or more places at a location;
detect an electricity data signature;
determine a device that is associated with the signature by one or more of:
comparing the detected signature with a local library of stored signatures;
comparing the detected signature with an external library of stored signatures; and
comparing the detected signature with a device behavior model;
monitor electricity patterns of the location;
determine, from the electricity patterns, states of the devices within the location, without there being an electricity data sensor individually dedicated to every device for which a state is determined;
communicate a first notification of a first determined state to a user interface, wherein the first determined state is an “on” state of a selected one of said devices that is different from an immediately preceding “on” state of said selected device, and the selected device does not have a dedicated electricity data sensor;
communicate a second notification of a second determined state of a non-smart one of said devices to a smart one of said devices, upon which the smart device changes its own state; and
communicate a third notification to a cloud service, receive from the cloud service an advertisement related to the determined state, and display the advertisement on the user interface.
